(19) United States
(12) Patent Application Publication
(10) Pub. No.: US 2010/0313633 A1
(43) Pub. Date: Dec. 16, 2010

(54) ESTIMATING EFFECTIVE PERMEABILITIES

(75) Inventors: VIVEK ANAND, Houston, TX (US); Robert Freedman, Houston, TX (US)

Correspondence Address: SCHLUMBERGER INFORMATION SOLUTIONS, 5599 SAN FELIPE, SUITE 1700, HOUSTON, TX, 77056-2722, US

(73) Assignee: SCHLUMBERGER TECHNOLOGY CORPORATION, Houston, TX (US)

(21) Appl. No.: 12/637,958

(22) Filed: Dec. 15, 2009

Related U.S. Application Data
(60) Provisional application No. 61/186,210, filed on Jun. 11, 2009.

(51) Int. Cl. G01N 15/08; G01R 33/44

(52) U.S. Cl. 73/38; 324/303

(57) ABSTRACT

A method for determining effective permeabilities of earth formations. The method includes receiving a database having one or more measurements made on a collection of fluid filled rocks and dividing the measurements into input measurements and output measurements. The input measurements include one or more measured properties of the fluid filled rocks and the output measurements include the corresponding effective permeabilities of the fluid filled rocks. The method then includes constructing a mapping function using the input measurements and the output measurements. The mapping function may then be used to predict the effective permeabilities of one or more rocks that are not part of the collection of fluid filled rocks. As such, the method may then include receiving one or more input measurements made on one or more rocks that are not part of the collection of fluid filled rocks and predicting the effective permeabilities of the rocks using the mapping function and the input measurements made on the rocks.

### RELATED APPLICATIONS

This application claims priority to U.S. provisional patent application Ser. No. 61/186,210, filed Jun. 11, 2009, titled METHOD FOR ESTIMATION OF EFFECTIVE PERMEABILITY OF SANDSTONE AND CARBONATE FORMATIONS, which is incorporated herein by reference.

### BACKGROUND

1. Field of the Invention

Implementations of various technologies described herein generally relate to techniques for determining effective permeabilities of earth formations and, more particularly, to techniques for determining such effective permeabilities using measurements in the earth formations.

2. Description of the Related Art

The following descriptions and examples are not admitted to be prior art by virtue of their inclusion within this section. The interpretation of well logging and geophysical measurements generally involves formulating and solving a mathematical inverse problem. That is, typically, one would like to predict the physical properties of some underlying physical system, such as effective permeabilities, from a suite of measurements. For example, the suite of measurements could be from a borehole logging tool or a suite of tools for which the underlying physical system is the porous fluid-filled rock formations surrounding the borehole. In this case, the physical properties predicted from the measurements might include porosities, fluid types and saturations, and bed thicknesses. For geophysical exploration, the measurements could be surface measurements of reflected seismic wave energy as a function of wavelength made at different receiver locations. In this case, the underlying physical system is the subsurface consisting of layers of porous sediments. The physical properties of most interest are those of the hydrocarbon-bearing layers.

Effective permeability is one of the physical properties of the underlying physical system that may be predicted by solving the inverse problems. Effective permeability is the ability to preferentially flow or transmit a particular fluid through a rock in the presence of other immiscible fluids in the reservoir. The estimation of effective permeability assists in reservoir development and management. For example, permeability is used for determining production rates and optimal drainage points, optimizing completion and perforation design, and devising enhanced oil recovery (EOR) patterns and injection conditions.

Currently, there are three methods commonly employed for in-situ estimation of permeability. The first method uses pressure transient tests, such as formation testers (e.g., Schlumberger Modular Dynamics Tester (MDT)), to measure the transient build up in the pore pressure following an extraction of a fixed volume of formation fluid. Under suitable assumptions of flow regime near the probe, the effective permeability (kₑ) of the formation can be related to the pressure build up. However, there are several limitations to this estimation method. First, most conventional tests measure transmissivity (kₑh/μ) during radial flow, and the reservoir thickness (h) and viscosity of the fluid (μ) may not be known. Second, pressure measurements are influenced by the presence of skin in the near-probe region. As such, if the presence of skin is not accounted for, the estimates of permeability from pressure measurements may be incorrect. Third, the pressure transient tests usually yield the effective permeability of the mud filtrate in the invaded zone rather than the effective permeability of formation fluids measured. Fourth, the estimation of permeability from transient tests requires matching the transient to type curves and formation models. Because of these factors, the permeability estimates from pressure transient tests remain qualitative.

The second method for in-situ estimation of permeability uses continuous log data. These data provide a continuous survey of formation properties such as porosity, irreducible water saturation and Nuclear Magnetic Resonance (NMR) parameters. Empirical and semi-empirical correlations have been developed that relate the absolute permeability of the formation to NMR parameters. The following two correlations, called the Schlumberger Doll Research (SDR) model and the Timur-Coates model respectively, are commonly employed for estimation of permeability from NMR log data:

k=a_{SDR}φ⁴T_{2LM}²

$$k = {a}_{coates} {{φ}^{4} ( \frac{FFI}{BVI} )}^{2}$$

where k is the absolute or brine permeability, φ is the formation porosity, T_{2,LM} is the logarithmic mean of the water T₂ distribution, FFI and BVI are the free fluid index and bound volume irreducible. A lithology specific T_{2,cutoff} is employed to partition the T₂ distribution into bound and free fluid components. A major limitation of determining permeabilities using the equations above is that the parameters a_{SDR}, a_{coates} and T_{2cutoff} are not universal and need to be calibrated for each reservoir area. Additionally, the correlations provide estimates of the absolute permeability (permeability at 100% water saturation) of the formation and not the effective permeability, which is the more useful parameter.

The third method for in-situ estimation of permeability includes using production tests and production history. An estimate of in-situ permeability can be obtained from flow rate and pressure data during steady-state production, preferably from specific tests at different flow rates. Another estimation method involves adjusting the permeability to match a history of production data. Both methods suffer from non-uniqueness of the solution of highly non-linear inverse problems. Furthermore, only an average value of permeability can be obtained.

The examples above show that there is a need for a method that provides a quantitative and more accurate estimate of formation effective permeability. Moreover, there is a need for a method to be independent of adjustable parameters that need to be calibrated for different reservoirs. The method should also provide a continuous estimate of permeability.

### SUMMARY

Described herein are implementations of various technologies for determining effective permeabilities of earth formations. In one implementation, a method for determining effective permeabilities of earth formations may include receiving a database having one or more measurements made on a collection of fluid filled rocks. The method may then include dividing the measurements into input measurements and output measurements. The input measurements may describe one or more measured properties of the fluid filled rocks and the output measurements may describe effective permeabilities of the fluid filled rocks. The method may then include constructing a mapping function using the input measurements and the output measurements. After the mapping function is constructed, the method may include receiving one or more input measurements made on one or more rocks that are not part of the collection of fluid filled rocks. The method may then include predicting effective permeabilities of the rocks using the mapping function and the input measurements made on the rocks.

The claimed subject matter is not limited to implementations that solve any or all of the noted disadvantages. Further, the summary section is provided to introduce a selection of concepts in a simplified form that are further described below in the detailed description section. The summary section is not intended to identify key or essential features of the claimed subject matter, nor is it intended to be used to limit the scope of the claimed subject matter.

### BRIEF DESCRIPTION OF THE DRAWINGS

Implementations of various technologies will hereafter be described with reference to the accompanying drawings. It should be understood, however, that the accompanying drawings illustrate only the various implementations described herein and are not meant to limit the scope of various technologies described herein.

FIG. 1 illustrates a schematic diagram of a logging apparatus in accordance with implementations of various techniques described herein.

FIG. 2 illustrates a graph indicating a predicted absolute permeability for carbonate cores estimated by a SDR and a Timur-Coates model versus measured effective permeability to oil in accordance with implementations of various techniques described herein.

FIG. 3 illustrates a graph indicating a predicted absolute permeability for sandstone cores estimated by a SDR and a Timur-Coates model versus measured effective permeability to oil in accordance with implementations of various techniques described herein.

FIG. 4 illustrates flow diagram of a method for estimating effective permeabilities in accordance with implementations of various techniques described herein.

FIG. 5 illustrates a graph indicating a predicted effective permeability to oil for carbonate cores estimated by a radial basis function interpolation technique in accordance with implementations of various techniques described herein.

FIG. 6 illustrates a graph indicating a predicted effective permeability to oil for sandstone cores estimated by a radial basis function interpolation technique in accordance with implementations of various techniques described herein.

FIG. 7 illustrates a computer network into which implementations of various technologies described herein may be implemented.

### DETAILED DESCRIPTION

The discussion below is directed to certain specific implementations. It is to be understood that the discussion below is only for the purpose of enabling a person with ordinary skill in the art to make and use any subject matter defined now or later by the patent “claims” found in any issued patent herein.

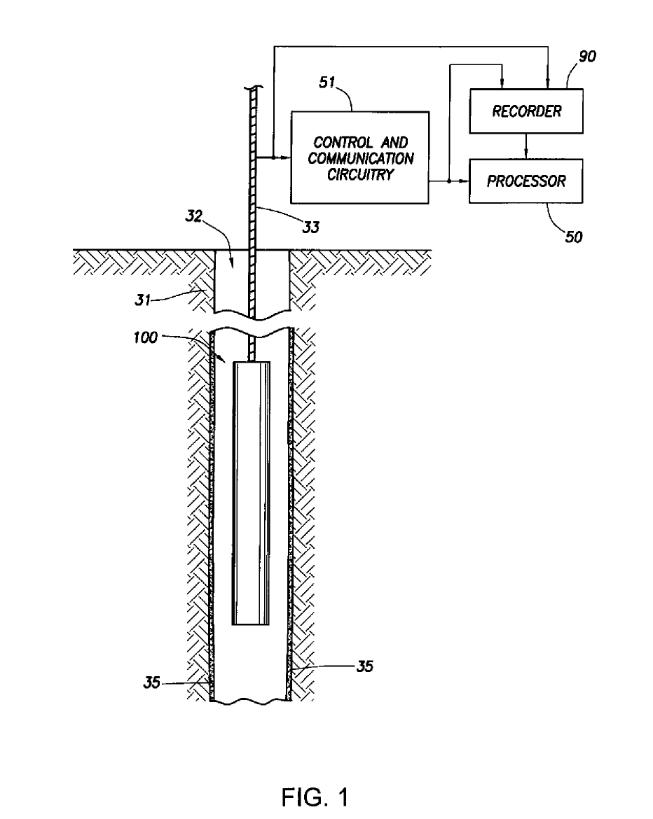

The following provides a brief description of various technologies and techniques for estimating effective permeabilities. In one implementation, a computer application may receive a database that includes measurements made on a collection of fluid filled rocks. The measurements may have been made using a well logging device or in a laboratory. In either case, the computer application may divide the measurements in the database into input measurements and output measurements. The input measurements may include one or more measured properties of the fluid filled rocks, and the output measurements may include the corresponding effective permeabilities of the fluid filled rocks. The computer application may then generate the mapping function by correlating the input measurements to their corresponding output measurements (i.e., effective permeabilities). After generating the mapping function, the computer application may receive one or more input measurements pertaining to one or more rocks that were not part of the collection of fluid filled rocks that was used to create the mapping function. The computer application may then predict the output measurements or the effective permeabilities of the rocks that were not part of the collection of fluid filled rocks using the mapping function and the input measurements of the rocks. FIGS. 1-6 illustrate one or more implementations of various techniques described herein in more detail.

FIG. 1 shows a borehole 32 that has been drilled in formations 31 with drilling equipment, and typically, using drilling fluid or mud that results in a mudcake represented at 35. A logging device 100 is shown, and can be used in connection with various implementations described herein. The logging device 100 may be suspended in the borehole 32 on an armored multiconductor cable 33. Known depth gauge apparatus (not shown) is provided to measure cable displacement over a sheave wheel (not shown), and thus the depth of the logging device 100 in the borehole 32. Circuitry 51, represents control and communication circuitry for the investigating apparatus. Although circuitry 51 is shown at the surface, portions thereof may typically be downhole. Also shown at the surface are processor 50 and recorder 90. Further, although the logging device 100 is shown to be a wireline logging tool, it should be noted that other tools, such as a logging while drilling tool, may be used in connection with various implementations described herein.

The logging device 100 may represent any type of logging device that takes measurements from which formation characteristics can be determined, for example, by solving complex inverse problems. The logging device 100 may be an electrical type of logging device (including devices such as resistivity, induction, and electromagnetic propagation devices), a nuclear logging device, a sonic logging device, or a fluid sampling logging device, or combinations thereof. Various devices may be combined in a tool string and/or used during separate logging runs. Also, measurements may be taken during drilling and/or tripping and/or sliding. Examples of the types of formation characteristics that can be determined using these types of devices include: determination, from deep three-dimensional electromagnetic measurements, of distance and direction to faults or deposits, such as salt domes or hydrocarbons; determination, from acoustic shear and/or compressional wave speeds and/or wave attenuations, of formation porosity, permeability, and/or lithology; determination of formation anisotropy from electromagnetic and/or acoustic measurements; determination, from attenuation and frequency of a rod or plate vibrating in a fluid, of formation fluid viscosity and/or density; determination, from resistivity and/or nuclear magnetic resonance (NMR) measurements, of formation water saturation and/or permeability; determination, from count rates of gamma rays and/or neutrons at spaced detectors, of formation porosity and/or density; and determination, from electromagnetic, acoustic and/or nuclear measurements, of formation bed thickness.

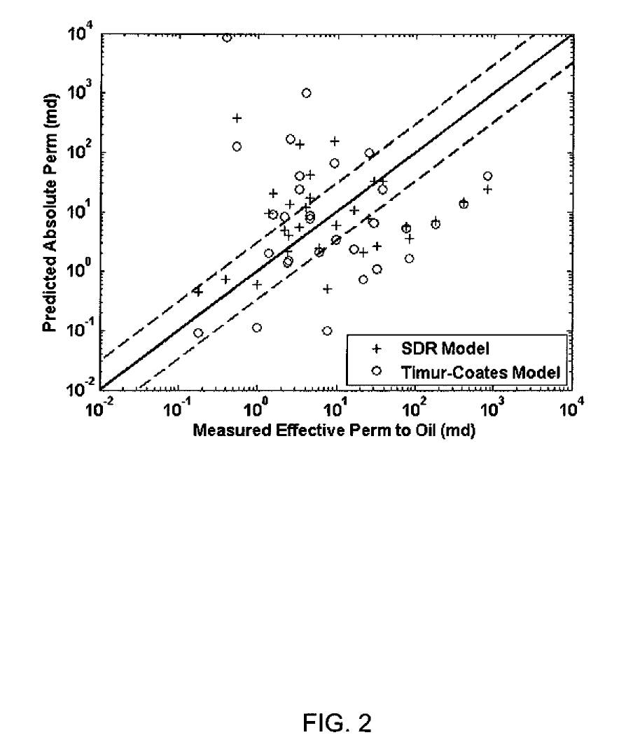

FIG. 2 illustrates a graph 200 indicating a predicted absolute permeability for carbonate cores estimated by a SDR and a Timur-Coates model versus measured effective permeability to oil in accordance with implementations of various techniques described herein. Graph 200 compares the absolute permeabilities of 37 carbonate cores estimated by the SDR and the Timur model with the effective oil permeabilities measured in a laboratory. In the estimation of absolute permeabilities, the values of a_{SDR}=0.07 and a_{coates}=2.7·10⁻⁶ were used. The solid black line is the best-fit line and the dashed lines are located at a deviation factor of 3. As shown in FIG. 2, the SDR and Timur-Coates model estimates provide a poor correlation between the estimated absolute permeabilities and the measured effective permeabilities for carbonate cores.

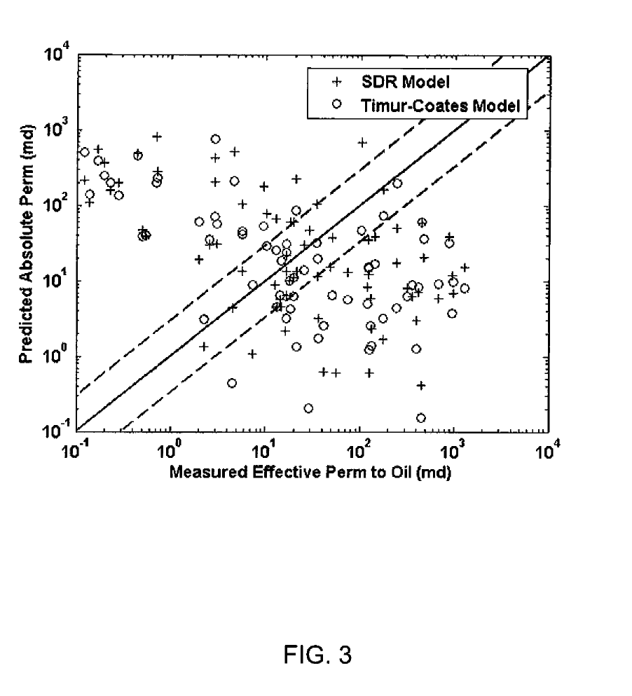

FIG. 3 illustrates a graph 300 indicating a predicted absolute permeability for sandstone cores estimated by a SDR and a Timur-Coates model versus measured effective permeability to oil in accordance with implementations of various techniques described herein. Graph 300 compares the absolute permeabilities of 80 sandstone cores estimated by the SDR and the Timur model with the effective oil permeabilities measured in a laboratory. In the estimation of absolute permeabilities, the values of a_{SDR}=0.06 and a_{coates}=1.5·10⁻⁵ were used. The solid black line is the best-fit line and the dashed lines are located at a deviation factor of 3. As shown in FIG. 3, the SDR and Timur-Coates model estimates provide a poor correlation between the estimated absolute permeabilities and the measured effective permeabilities for sandstone cores.

The preceding description of FIGS. 2 and 3 illustrates a traditional approach (e.g., using simple empirically derived equations like the SDR and Timur-Coates models) for solving mathematical inverse problems that may be used to interpret well logging measurements obtained from logging device 100 or to interpret geophysical measurements obtained from a laboratory. The traditional approach includes fitting a theoretical or empirically derived forward model (e.g., SDR model, Timur-Coates model) to measurement data (see e.g., the book by A. Tarantola, “Inverse Problem Theory: Methods For Data Fitting And Model Parameter Estimation”, published by Elsevier, Amsterdam, The Netherlands, 1987). The forward model is a function of a set of model parameters that are either identical to or related to the physical properties of the underlying physical system. Selecting the values of the model parameters that minimize the difference between the actual measurements and those predicted by the forward model is assumed to solve the inverse problem. This basic assumption is itself fraught with difficulties and can lead to erroneous solutions because most well logging and geophysical inverse problems are ill posed, i.e., the solutions are not unique. This traditional approach has other inherent limitations and caveats that render it unsuitable or too computationally expensive for providing accurate solutions to many problems of interest.

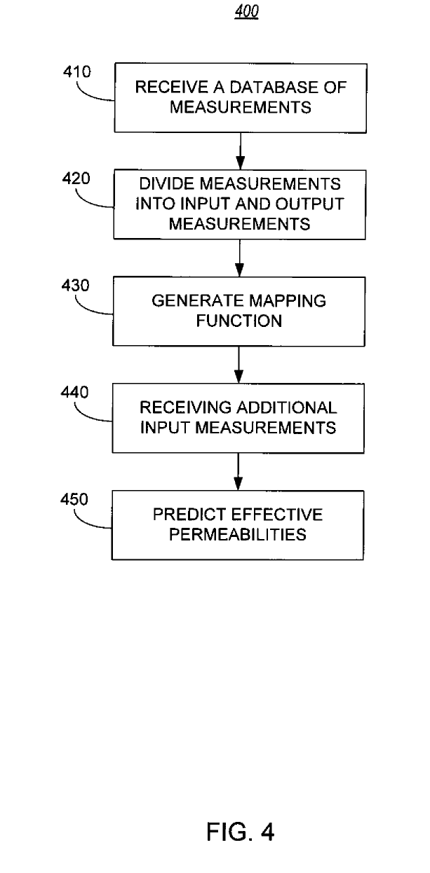

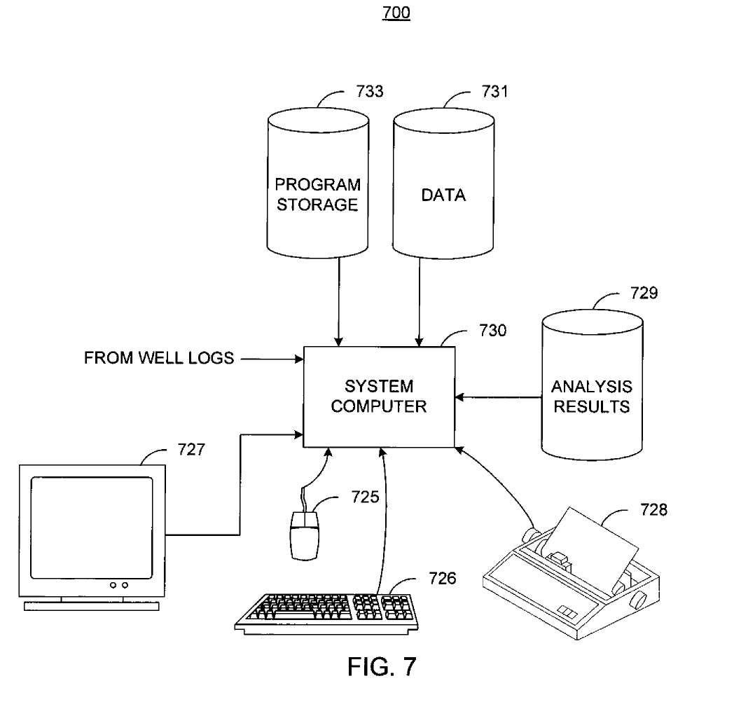

FIG. 4 illustrates flow diagram of a method 400 for estimating effective permeabilities in accordance with implementations of various techniques described herein. It should be understood that while method 400 indicates a particular order of execution of the operations, in some implementations, certain portions of the operations might be executed in a different order. In one implementation, method 400 may be performed by a system computer which will be described in more detail with reference to FIG. 7.

At step 410, the system computer may receive a database containing measurements that have been made on a collection of fluid filled rocks. In one implementation, the measurements may be obtained from laboratory measurements with core plugs. The laboratory measurements may be obtained by performing one or more tests on the collection of fluid filled rocks to determine certain characteristics of the fluid filled rocks, such as fluid porosity, saturation, Nuclear Magnetic Resonance (NMR) T2 response, NMR T1 response, viscosity, effective permeabilities and the like. In another implementation, the data may be obtained from well logging devices, such as the logging device 100 illustrated in FIG. 1. The fluid filled rocks may be rocks or earth formations of any type that may be found at or near wells, such as carbonates, sandstones and the like.

In one implementation, the input measurements may include well log measurements that may be made routinely by logging service companies. Porosity may be the most basic well logging measurement. Porosity may be determined from neutron and density logs, NMR derived porosities or combinations thereof. Porosity may also be derived from acoustic or dielectric well logging measurements.

Water saturation may also be derived from resistivity and dielectric logs using porosity and other log inputs. Water saturation may also be derived from NMR tool diffusion measurements. The derivation of porosity and water saturation from well log data is well-known to anyone skilled in the art of well-logging formation evaluation. Nuclear Magnetic Resonance (NMR) T2 response may be derived from NMR logging tool measurements.

At step 420, the system computer may divide the measurements in the database into input and output measurements. In one implementation, dividing the measurements into input and output measurements may include designating a portion of the measurements made on the collection of fluid filled rocks as input measurements and the remaining portion as output measurements. Both the input and output measurements may include various formation properties of the collection of fluid filled rocks, but the output measurements may include information that is being sought. For example, in the method for estimating effective permeabilities described herein, the output measurements may include the effective permeabilities of the collection of fluid filled rocks because one may be seeking to predict the effective permeabilities of one or more rocks that are not part of the collection of fluid filled rocks. Although the method described herein is directed at estimating effective permeabilities, it should be noted that the method described herein may also be used to estimate various other properties of rocks.

At step 430, the system computer may generate a mapping function based on the input measurements and the output measurements identified at step 420. In one implementation, the mapping function may approximate the underlying physical relationship between the input measurements and the output measurements. For instance, the mapping function may approximate the relationship between the characteristics of the fluid filled rocks, such as fluid porosity, saturation, NMR T2 response, NMR T1 response (i.e., input measurements) and the effective permeabilities of the fluid filled rocks (i.e., output measurements). In this manner, the mapping function may be visualized as a multivariate interpolation between the input measurements in the database and the effective permeabilities.

The mapping function may be generated or constructed using a linear combination of one or more non-linear functions or using a weighted sum of one or more non-linear functions. In one implementation, the mapping function may be generated using radial basis functions. Radial basis functions (RBF) are real-valued functions whose values depend on the distance from the origin, so that φ(x)=φ(∥x∥); or alternatively on the distance from some other point c, (i.e., center), so that φ(x,c)=φ(∥x−c∥). Additional details relating to the radial basis functions are described below.

### Radial Basis Function

In one implementation, let \vec{ƒ}(\vec{x}), \vec{x}∈R″ and \vec{ƒ}∈R′″, be a real valued vector function of n variables, and let values of \vec{ƒ}(\vec{x}ᵢ)≡\vec{y}ᵢ be given at N distinct points, \vec{x}ᵢ. The interpolation problem is to construct function \vec{F}(\vec{x}), that approximates \vec{f}(\vec{x}) and satisfies the interpolation equations,

\vec{F}(\vec{x}ᵢ)=\vec{y}ᵢ, i=1, 2, . . . , N. (1)

RBF interpolation chooses an approximating or mapping function of the form,

$$\vec{F} ( \vec{x} ) = {\sum }_{i = 1}^{N} {\vec{c}}_{i} ϕ ( ‖ \vec{x} - {\vec{x}}_{i} ‖ ) . \qquad ( 2 )$$

The non-linear functions φ(∥\vec{x}−\vec{xᵢ}∥) are called “radial” because the argument of the function depends only on the distance between \vec{xᵢ} and an arbitrary input vector \vec{x}. The argument is given by the Euclidean norm in the n-dimensional hyper space, i.e.,

$$‖ \vec{x} - {\vec{x}}_{i} ‖ = \sqrt{{\sum }_{m = 1}^{n} {( {x}_{m} - {x}_{m , i} )}^{2}} . \qquad ( 3 )$$

The weights or coefficients, \vec{c}ᵢ in Equation (2) are determined by requiring that the interpolation equations (1) be satisfied exactly. In one implementation, the system computer may calibrate the coefficients of the mapping function such that the interpolation of the input measurements to the output measurements is exact. As such, the coefficients are a linear combination of the given function,

$${\vec{c}}_{i} = {\sum }_{j = 1}^{N} {Φ}_{i , j}^{- 1} \cdot {\vec{y}}_{j} . \qquad ( 4 )$$

where Φ_{i,j}≡φ(∥\vec{x}ᵢ−\vec{xⱼ}∥) is the, N×N , interpolation matrix.

One of the advantages in using the radial basis functions is that for certain functional forms that include Gaussians, multiquadrics, and inverse multiquadrics, mathematicians have proven that the interpolation matrix is non-singular (e.g., Micchelli, “Interpolation of scattered data: Distance matrices and conditionally positive definite functions,” Constructive Approximation, v. 2, 11-22, 1986). This means that the mapping function in Equation (2) can be uniquely determined. Radial basis function interpolation has other attractive properties not possessed by classical interpolation schemes such as polynomial splines or finite difference approximations. First, radial basis function interpolation is more accurate than classical methods for the approximation of multivariate functions of many variables. Second, radial basis function interpolation does not require the data to be on a uniform lattice and has been shown to work well with scattered data sets (M. Buhmann, Radial Basis Functions: Theory and Implementation, 2003, Cambridge University Press). Third, numerical experiments have shown the somewhat surprising result that for a given number of data points, N, the accuracy of the interpolation is independent of the number of independent variables, n, even for very large n (M. J. D. Powell, “Radial basis function methods for interpolation to functions of many variables,” presented at the 5^{th} Hellenic-European Conference on Computer Mathematics and its Application, 1-23, 2001).

The above referenced paragraphs describe the mathematical properties for radial basis function interpolation. The following paragraphs describe how the radial basis functions may be used for approximating functions of many variables to generate the mapping function.

Generating the mapping function may include solving inverse problems that involve predicting the physical properties of an underlying system (i.e., output measurements), given the set of input measurements. In one implementation, consider the database having a set of input measurements \vec{x}ᵢ∈R″ (i.e., the input measurements are n-dimensional vectors) and a set of corresponding output measurements, \vec{y}ᵢ∈R′″, for i=1, . . . , N where N is the number of cases in the database. In the mathematical language of RBF interpolation, the output measurements \vec{y}ᵢ represent samples of the function that the system computer may want to approximate and \vec{x}ᵢ, are the distinct points at which the function is given. The input measurements, \vec{x}ᵢ,represent the measurements from which the output measurements, \vec{y}ᵢ, of the underlying system are to be predicted. The output measurements, \vec{y}ᵢ, may include the physical properties of the underlying system, such as effective permeabilities. The mapping function may be configured such that given input measurements \vec{x} that are not in the database received at step 410, the system computer may predict the output measurements, \vec{y}(\vec{x}), (i.e., permeabilities) of the physical system consistent with the input measurements. As such, the mapping function solves the inverse problem by predicting the physical properties of the system from the input measurements.

In one implementation, the radial basis functions used in the implementations described herein may be normalized Gaussian radial basis functions defined by the equation,

$$ϕ ( ‖ \vec{x} - {\vec{x}}_{i} ‖ ) = \frac{exp ( - \frac{{‖ \vec{x} - {\vec{x}}_{i} ‖}^{2}}{2 {s}_{i}^{2}} )}{{\sum }_{j = 1}^{N} exp ( - \frac{{‖ \vec{x} - {\vec{x}}_{j} ‖}^{2}}{2 {s}_{j}^{2}} )} . \qquad ( 5 )$$

In other implementations, other radial basis functions, such as exponential, multiquadrics, or inverse multiquadrics, may also be used. These functions may be normalized in the sense that the summation over the input measurements, \vec{x}ᵢ, is equal to unity for all \vec{x}, i.e.,

$${\sum }_{i = 1}^{N} ϕ ( ‖ \vec{x} - {\vec{x}}_{i} ‖ ) = 1. \qquad ( 6 )$$

As such, it is easily seen from Equation (5) that,

φ(∥\vec{x}−\vec{x}ᵢ∥)≦1. (7)

By combining Equations 2 and 5, the mapping function for Gaussian radial basis functions may be written as

$$\vec{F} ( \vec{x} ) = \frac{{\sum }_{i = 1}^{N} {\vec{c}}_{i} exp ( - \frac{{‖ \vec{x} - {\vec{x}}_{i} ‖}^{2}}{2 {s}_{i}^{2}} )}{{\sum }_{i = 1}^{N} exp ( - \frac{{‖ \vec{x} - {\vec{x}}_{i} ‖}^{2}}{2 {s}_{i}^{2}} )} . \qquad ( 8 )$$

The width, Sᵢ, of the Gaussian radial basis function centered at \vec{x}ᵢ is representative of the range or spread of the function in the input space. The optimal widths, for accurate approximations, should be of the order of the nearest neighbor distances in the input space. The idea is to pave the input space with basis functions that have some overlap with nearest neighbors but negligible overlap for more distant neighbors. This ensures that for an input measurement \vec{x} that is not in the data base the output \vec{F}(\vec{x}) will be computed as a weighted average of contributions from those input measurements \vec{x}ᵢ that are nearest to the input measurement \vec{x}.

An intuitive understanding of how the mapping function in Equation 8 predicts an output vector for an input vector not in the data base can be gained by considering the Nadaraya-Watson Regression Estimator (NWRE). The NWRE is based on a simple approximation for the weight vectors (S. Haykin, Neural Networks: A Comprehensive Foundation, Prentice Hall, Hamilton Ontario, Canada, 1999). The interpolation equations for the mapping function in Equation 8 can be written in the form,

$$\vec{F} ( {\vec{x}}_{j} ) = \frac{{\vec{c}}_{j} + {\sum }_{{i = 1}_{i \neq j}}^{N} {\vec{c}}_{i} exp ( - \frac{{‖ {\vec{x}}_{j} - {\vec{x}}_{i} ‖}^{2}}{2 {s}_{i}^{2}} )}{1 + {{\sum }_{{i = 1}_{i \neq j}}}^{N} exp ( - \frac{{‖ {\vec{x}}_{j} - {\vec{x}}_{i} ‖}^{2}}{2 {s}_{i}^{2}} )} . \qquad ( 9 )$$

The summations in Equation (9) can be neglected if one neglects the overlap of the data base radial basis functions. The NWRE approximation assumes that the interpolation matrix in Equation 4 is diagonal and leads to a simple approximation for the coefficient vectors,

\vec{F}(\vec{x}ⱼ)≡\vec{y}ⱼ=\vec{c}ⱼ. (10)

This simple approximation replaces the coefficient vectors in Equation 8 by the database output vectors, \vec{y}ᵢ. It turns out that for many practical problems the NWRE approximation works very well and may be a good starting point. Computing the coefficients using Equation (4) provides a refinement to the approximation. As such, combining Equations (8) and (10) the system computer may determine the NWRE mapping function to be

$$\vec{F} ( \vec{x} ) ≅ \frac{{\sum }_{i = 1}^{N} {\vec{y}}_{i} exp ( - \frac{{‖ \vec{x} - {\vec{x}}_{i} ‖}^{2}}{2 {s}_{i}^{2}} )}{{\sum }_{i = 1}^{N} exp ( - \frac{{‖ \vec{x} - {\vec{x}}_{i} ‖}^{2}}{2 {s}_{i}^{2}} )} . \qquad ( 11 )$$

Note that in the limit of very large sᵢ, \vec{F}(\vec{x}) approaches the sample mean of the data base output vectors. In the limit of very small sᵢ, \vec{F}(\vec{x})approaches the output vector \vec{y}ⱼ corresponding to the database input vector \vec{x}ⱼ that is closest \vec{x}. In general, \vec{F}(\vec{x}) is a weighted average of the database output vectors with weighting factors determined by the closeness of \vec{x} the database input vectors. It can be observed that the NWRE approximation in Equation 11 does not satisfy the interpolation conditions in Equation 1.

The NWRE approximation can be improved upon by determining optimal coefficient vectors such that the interpolation equations are satisfied. The problem is linear if the widths of the Gaussian radial basis functions are fixed. The interpolation conditions lead to a set of linear equations for the coefficient vectors whose solution can be written in matrix form, i.e.,

C=Φ⁻¹·Y (12)

where the, N×m , matrix, C , is given by,

$$C = [ \begin{matrix}{c}_{1.1} & {c}_{1.2} & … & {c}_{1. m} \\ {c}_{2.1} & {c}_{2.2} & … & {c}_{2. m} \\ ⋮ & ⋮ & ⋮ & ⋮ \\ ⋮ & ⋮ & ⋮ & ⋮ \\ {c}_{N .1} & {c}_{N .2} & … & {c}_{N . m}\end{matrix} ] \qquad ( 13 )$$

where the i-th row of C is the transpose of the coefficient vector for the i-th database case. That is, the first subscript on each coefficient runs from 1 to N and denotes a particular data base case and the second subscript denotes a particular element of the database output vectors and runs from 1 to m. The matrix φ whose inverse appears in Equation 12 is the, N×N , positive definite matrix of Gaussian radial basis functions, i.e.,

$$Φ = [ \begin{matrix}{ϕ}_{1 , 1} & {ϕ}_{1 , 2} & … & {ϕ}_{1 , N} \\ {ϕ}_{2 , 1} & {ϕ}_{2 , 2} & … & {ϕ}_{2 , N} \\ ⋮ & ⋮ & ⋮ & ⋮ \\ {ϕ}_{N , 1} & {ϕ}_{N , 2} & … & {ϕ}_{N , N}\end{matrix} ] \qquad ( 14 )$$

where the matrix elements are the normalized Gaussian radial basis functions,

$${ϕ}_{i , j} = \frac{exp ( - \frac{{‖ \vec{{x}_{i}} - {\vec{x}}_{j} ‖}^{2}}{2 {s}_{i}^{2}} )}{{\sum }_{j = 1}^{N} exp ( - \frac{{‖ \vec{{x}_{i}} - {\vec{x}}_{j} ‖}^{2}}{2 {s}_{j}^{2}} )} . \qquad ( 15 )$$

The N×m matrix, Yin Equation 12 contains the database output vectors, e.g.,

$$Y = [ \begin{matrix}{y}_{1 , 1} & {y}_{1 , 2} & … & {y}_{1 , m} \\ {y}_{2 , 1} & {y}_{2 , 2} & … & {y}_{2 , m} \\ ⋮ & ⋮ & ⋮ & ⋮ \\ {y}_{N , 1} & {y}_{N , 2} & … & {y}_{N , m}\end{matrix} ] . \qquad ( 16 )$$

Note that the i-th row is the transpose of the data base vector \vec{y}ᵢ. The solution for the coefficients given in Equations 12-16 improves on the NWRE approximation by determining optimal coefficient vectors with the caveat of having fixed widths for the Gaussian radial basis functions. It can be proved mathematically that the matrix φ is non-singular for certain functional forms of RBFs, including Gaussian, multiquadric, and inverse quadrics. This property ensures that the mapping function of Equation (2) is unique. Hence, using a database with N samples, a mapping, i.e., interpolating, function that is consistent with the measurements can be uniquely defined from Equation (13). For an unknown sample not included in the database, the desired output may then be obtained by evaluating the mapping function at the corresponding input i.e.,

\vec{y}=F(\vec{x}) (17)

Referring back to FIG. 4, at step 440, the system computer may receive one or more input measurements pertaining to one or more rocks that are not part of the collection of fluid filled rocks in the database received at step 410. In one implementation, the rocks that are not part of the collection of fluid filled rocks include rocks that are related to hydrocarbons. The input measurements pertaining to the rocks that are not part of the collection of fluid filled rocks may include characteristics, such as fluid porosity, saturation, NMR T2 response, NMR T1 response and the like.

At step 450, the system computer may then predict the effective permeabilities (i.e., output measurements) from the input measurements received at step 440 using the mapping function created at step 430.

### Applications to Reservoir Characterization

As shown above, the mapping function generated at step 430 may be used to predict the effective permeabilities of rocks using the input measurements on those rocks. In reservoir engineering nomenclature, such effective permeabilities are usually denoted by the symbol, kₒ(S_{w}). In one implementation, many oil reservoirs encountered in practice are at irreducible water saturation, kₒ(S_{wi}), and the mapping functions generated at step 430 may be directly applied to borehole well logging measurements in such reservoirs to predict the corresponding effective permeabilities of the rocks within the borehole. This implementation will be discussed in more details in the paragraphs below. However, it should be understood that in other implementations, the mapping functions generated at step 430 may be directly applied to borehole well logging measurements in reservoirs that are at other saturations to predict the corresponding effective permeabilities of the rocks within the borehole.

It is worth noting that the effective permeability to water at irreducible water saturation is defined as k_{w}(S_{wi})≡0. As such, oil reservoirs at irreducible water saturation should flow oil and no water (i.e., the water cut should be zero). In such reservoirs, a continuous depth log of effective permeabilities to oil, kₒ(S_{wi}), would be a useful new reservoir quality characterization parameter. In one implementation, the continuous depth log of effective permeabilities may be derived by the predicted effective permeabilities. The continuous depth log of effective permeabilities to oil may be useful in making well to well comparisons of reservoir quality in a development field. The continuous depth log of effective permeabilities to oil may also be useful for selecting zones to complete a single well and in choosing perforation depths for optimal flow rates in a single well. In one implementation, the continuous depth logs of the earth formations in a reservoir may be predicted using the predicted effective permeabilities, predicted flow rates, predicted mobilities, a fractional water flow of rocks, or combinations thereof. One or more implementations for predicting flow rates, mobilities and fractional water flow of rocks are described below.

In another implementation, the predicted effective permeabilities may be used to predict the flow rates of one or more fluids in the rocks that are not part of the collection of fluid filled rocks. Here, the predicted effective permeabilities may be used to construct a “producibility index” from the oil mobility (M) which is defined as the effective permeability to oil divided by oil viscosity (η), e.g.,

$$M = \frac{{k}_{0}}{η} . \qquad ( 18 )$$

The flow rate is proportional to mobility and a depth log of mobility in a borehole may be used as a parameter for choosing completion zone depths and location of perforations in a well. As such, the effective permeabilities may also be used to predict the mobilities of fluids in the rocks that are not part of the collection of fluid filled rocks.

The mobilities of fluids may then be used to select casing perforation depths in a borehole in order to optimize production rates.

Effective permeabilities may also be used as inputs in reservoir simulation models. In one implementation, a more quantitative prediction of flow rates (i.e., production rate) may be obtained by solving Navier-Stokes equations or Darcy's equations for multi-phase flow. Both of these equations are employed in reservoir engineering simulations. One input to the simulations may include the effective permeabilities of the reservoir fluids as a function of the wetting phase fluid saturation. These equations and their solutions are well-known to those skilled in reservoir engineering and flow in porous media. For example, Darcy's equation in differential form for the flow rate of oil in the presence of water can be written in the form, (e.g., see R. E. Collins, Flow of Fluids Through Porous Media, pp. 60-62),

$${\vec{v}}_{o} = - \frac{{k}_{o} ( {S}_{w} ) {ρ}_{o}}{{η}_{o}} \vec{∇} {Ψ}_{o} . \qquad ( 19 )$$

In Equation 19, \vec{v}ₒ is the mean flow rate per unit area, kₒ is the effective permeability to oil and is a function of the wetting phase saturation, pₒ is the oil density, ηₒ is the oil viscosity in the reservoir, and Ψₒ is the flow potential for the oil phase. It is understood that a similar equation for water flow can be written.

The mobilities of oil and water may then be used to predict the fraction of the total flow that will be water. The fraction of the total flow that will be water is the water-cut and is given approximately by (see equation 6-28 in Collins),

$${f}_{w} \approx \frac{1}{1 + \frac{{k}_{o} {η}_{w}}{{k}_{w} {η}_{o}}} . \qquad ( 20 )$$

Equation (20) is the water cut when water is displacing oil and may be used for a secondary recovery water flood or for primary production by a water drive. The simple form shown in Equation (20) may neglect capillary pressure and gravity effects.

Although method 400 has been described with reference to predicting effective permeabilities, it should be understood that in some implementations, method 400 may also be used to predict relative permeabilities. Relative permeabilities may be predicted by calculating the ratio of the effective permeability to an absolute permeability. The absolute permeability is a measurement of the permeability of a rock filled with a single fluid. In this implementation, the database containing measurements received at step 410 may include relative permeability data.

As shown in the foregoing discussion, the prediction of accurate effective fluid permeabilities may be an ingredient in the prediction of reservoir performance. As such, method 400 detailed above will lead to improved predictions of key reservoir performance factors including production rates, water cut, recoverable reserves, residual oil saturation, ultimate recovery and the like.

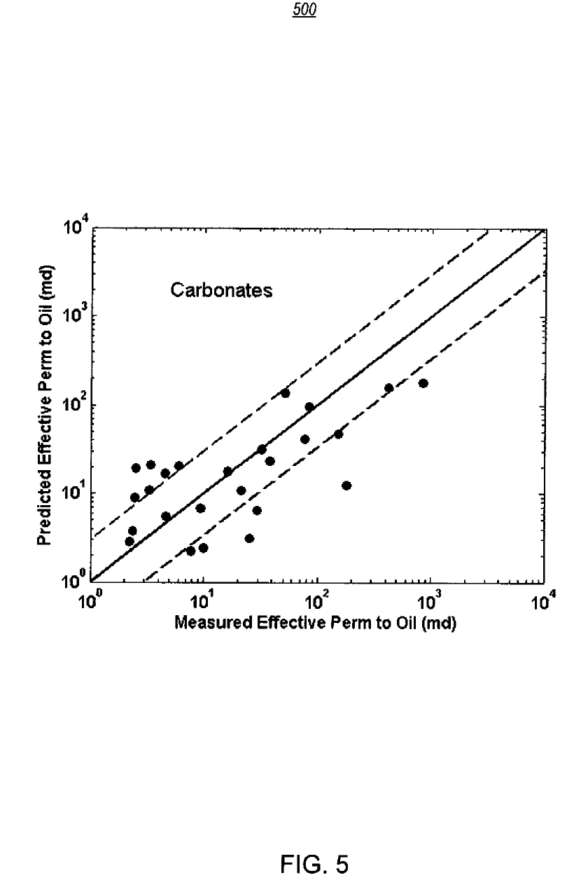

FIG. 5 illustrates a graph indicating a predicted effective permeability to oil for carbonate cores estimated by a radial basis function interpolation technique in accordance with implementations of various techniques described herein. In one implementation, the radial basis function interpolation technique may describe the mapping function generated at step 430. FIG. 5 uses a world-wide rock database consisting of petrophysical input measurements on carbonate cores to predict effective permeabilities of the carbonate cores. The carbonate cores may have been obtained from formations around the world and may have included carbonate cores of different geologic ages ranging from the Miocene period to the Ordovician period. Carbonate cores with a wide range of petrophysical and geological properties such as lithology, texture and porosity types may also have been included in the database. In particular, the database used in FIG. 5 consisted of carbonate rocks of two important lithologies namely, limestone and dolostone. The carbonate cores comprised of grainstone, packstone, wackestone, mudstone, boundstone, and crystalline texture. The porosity types of the cores included interparticle, intraparticle, intercrytalline, intracrystalline, moldic, vugular (touching and isolated) and fenestral. The pore filling minerals included calcite, dolomite, chert, anhydrite, clay and solid hydrocarbon.

The input measurement database consisted of core porosity, irreducible water saturation, effective permeability to oil at irreducible water saturation, and NMR response at irreducible water saturation. The porosity of the cores measured using helium expansion method varied from 5% to 35%. The effective permeability of oil at irreducible water saturation and 5000 psig confining pressure varied from 0.1 md to 1000 md. NMR response of oil saturated plugs at irreducible water saturation was measured at 2 MHz and 0.2 ms echo spacing.

From the mathematical formulation of RBFs described above, the effective permeabilities of the carbonate cores may be expressed as a linear combination of RBFs as shown below.

$${k}_{o} = \frac{{\sum }_{j = 1}^{N} {c}_{j} exp ( - \frac{{‖ {\vec{A}}_{T} - {\vec{A}}_{T , j} ‖}^{2}}{2 {s}_{j}^{2}} )}{{\sum }_{j = 1}^{N} exp ( - \frac{{‖ {\vec{A}}_{T} - {\vec{A}}_{T , j} ‖}^{2}}{2 {s}_{j}^{2}} )} \qquad ( 21 )$$

where N is the number of cores in the database. \vec{A}ᵣ is the input vector which includes porosity, irreducible water saturation and normalized amplitudes of the T₂ distribution. \vec{A}_{T} is defined as:

\vec{A}_{T}=\vec{A}_{T}(φ,S_{wi},A(T₂)) (22)

The amplitudes of the T₂ distribution for each sample are normalized with the largest respective values to eliminate the dependence on hardware and software settings. The widths of the Gaussian RBFs are proportional to the Euclidean nearest neighbor distance in the input space. Using Equation (21), the effective permeabilities of the carbonate cores were estimated from porosity, irreducible water saturation and amplitudes of T₂ distribution. The effective permeabilities of the samples were calculated from Equation (21) using the using the leave-one out method. The widths were heuristically determined to be half the nearest neighbor distances in the input space. The comparison of the estimated permeabilities with those measured in the laboratory is plotted in the graph of FIG. 5. As seen in FIG. 5, the effective oil permeabilities may be accurately predicted for suites of carbonate rocks using measurements of total rock porosity (φ), irreducible water saturation (S_{wi}), and a T2 distribution. For most carbonate cores, the permeability is estimated within a factor of 3 which is a significant improvement compared to the estimates of physical models as shown in FIG. 2.

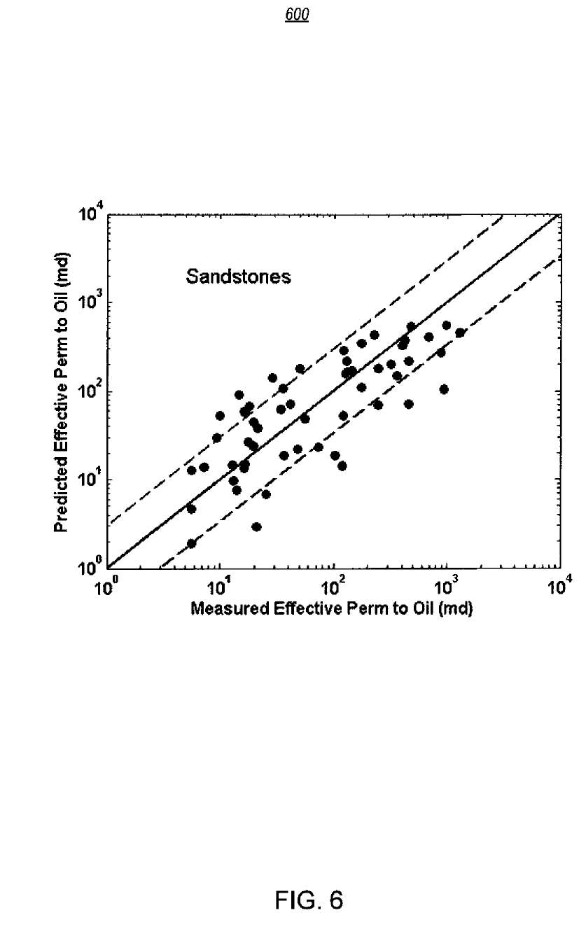

FIG. 6 illustrates a graph indicating a predicted effective permeability to oil for sandstone cores estimated by a radial basis function interpolation technique in accordance with implementations of various techniques described herein. In FIG. 6, a world-wide rock database consisting of petrophysical measurements on sandstone cores was used to determine the effective permeabilities to oil. The plugs were obtained from formations from around the world and were of different geologic ages ranging from the Pliocene period to the Devonian period. In this manner, the database incorporated core plugs from formations with a wide range of petrophysical and geological properties such as grain size, sorting, degree of consolidation and cement types. For example, the grain size of the core plugs ranged from silt size (<0.06 mm) to pebble size (>2 mm). The grain sorting varied from very well to very poor sorting. The database also included unconsolidated sands as well as consolidated sands with varying degree of consolidation.

The input measurements with the core plugs included porosity, irreducible water saturation, effective permeability to oil at irreducible water saturation, absolute permeability (100% water saturated), and T₂ distribution at irreducible water saturation. The porosity of the cores measured using helium expansion method varied from 5% to 35%. The effective permeability of oil measured at irreducible water saturation at 5000 psig confining pressure varied from 0.1 md to 1000 md. The T₂ distributions of the oil saturated core plugs at irreducible water saturation were measured at proton Larmor frequency of 2 MHz and 0.2 ms echo spacing. In some cases, the NMR response and effective permeability were measured with different cores that were derived from the same larger-sized (˜1 foot) plug. As such, the interpolation between T₂ distribution and effective permeability incorporates an error due to the heterogeneity of the formation over the length scale of the plug. This is not necessarily a disadvantage because log data, in general, may have similar or worse vertical resolution.

Using the mathematical formulation as shown above, the effective permeabilities of the cores can be expressed as a linear combination of RBFs as shown in Equations 21-22. FIG. 6 shows the comparison of the effective permeabilities estimated using Equation (21) with those measured in the lab. As seen in FIG. 6, the effective oil permeabilities may be accurately predicted for suites of sandstones using measurements of total rock porosity (φ), irreducible water saturation (S_{wi}), and a T2 distribution. For most cases, the effective permeability is estimated within a factor of 3, which is a significant improvement compared to the estimates of the physical models as shown in FIG. 3.

FIG. 7 illustrates a computing system 700, into which implementations of various techniques described herein may be implemented. The computing system 700 (system computer) may include one or more system computers 730, which may be implemented as any conventional personal computer or server. However, those skilled in the art will appreciate that implementations of various techniques described herein may be practiced in other computer system configurations, including hypertext transfer protocol (HTTP) servers, hand-held devices, multiprocessor systems, microprocessor-based or programmable consumer electronics, network PCs, minicomputers, mainframe computers, and the like.

The system computer 730 may be in communication with disk storage devices 729, 731, and 733, which may be external hard disk storage devices. It is contemplated that disk storage devices 729, 731, and 733 are conventional hard disk drives, and as such, will be implemented by way of a local area network or by remote access. Of course, while disk storage devices 729, 731, and 733 are illustrated as separate devices, a single disk storage device may be used to store any and all of the program instructions, measurement data, and results as desired.

In one implementation, measurements received at step 410 in method 400 may be stored in disk storage device 731. The system computer 730 may retrieve the appropriate data from the disk storage device 731 to predict effective permeabilities according to program instructions that correspond to implementations of various techniques described herein. The program instructions may be written in a computer programming language, such as C++, Java and the like. The program instructions may be stored in a computer-readable medium, such as program disk storage device 733. Such computer-readable media may include computer storage media and communication media. Computer storage media may include volatile and non-volatile, and removable and non-removable media implemented in any method or technology for storage of information, such as computer-readable instructions, data structures, program modules or other data. Computer storage media may further include RAM, ROM, erasable programmable read-only memory (EPROM), electrically erasable programmable read-only memory (EEPROM), flash memory or other solid state memory technology, CD-ROM, digital versatile disks (DVD), or other optical storage, magnetic cassettes, magnetic tape, magnetic disk storage or other magnetic storage devices, or any other medium which can be used to store the desired information and which can be accessed by the system computer 730. Communication media may embody computer readable instructions, data structures or other program modules. By way of example, and not limitation, communication media may include wired media such as a wired network or direct-wired connection, and wireless media such as acoustic, RF, infrared and other wireless media. Combinations of any of the above may also be included within the scope of computer readable media.

In one implementation, the system computer 730 may present output primarily onto graphics display 727, or alternatively via printer 728. The system computer 730 may store the results of the methods described above on disk storage 1029, for later use and further analysis. The keyboard 726 and the pointing device (e.g., a mouse, trackball, or the like) 725 may be provided with the system computer 730 to enable interactive operation.

The system computer 730 may be located at a data center remote from the region were the earth formations were obtained from. The system computer 730 may be in communication with the logging device described in FIG. 1 (either directly or via a recording unit, not shown), to receive signals indicating the measurements on the earth formations. These signals, after conventional formatting and other initial processing, may be stored by the system computer 730 as digital data in the disk storage 731 for subsequent retrieval and processing in the manner described above. In one implementation, these signals and data may be sent to the system computer 730 directly from sensors, such as well logs and the like. When receiving data directly from the sensors, the system computer 730 may be described as part of an in-field data processing system. In another implementation, the system computer 730 may process seismic data already stored in the disk storage 731. When processing data stored in the disk storage 731, the system computer 730 may be described as part of a remote data processing center, separate from data acquisition. The system computer 730 may be configured to process data as part of the in-field data processing system, the remote data processing system or a combination thereof. While FIG. 7 illustrates the disk storage 731 as directly connected to the system computer 730, it is also contemplated that the disk storage device 731 may be accessible through a local area network or by remote access. Furthermore, while disk storage devices 729, 731 are illustrated as separate devices for storing input seismic data and analysis results, the disk storage devices 729, 731 may be implemented within a single disk drive (either together with or separately from program disk storage device 733), or in any other conventional manner as will be fully understood by one of skill in the art having reference to this specification.

While the foregoing is directed to implementations of various technologies described herein, other and further implementations may be devised without departing from the basic scope thereof, which may be determined by the claims that follow. Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

What is claimed is:

1. A method for determining effective permeabilities of earth formations, comprising:
receiving a database having one or more measurements made on a collection of fluid filled rocks;
dividing the measurements into input measurements and output measurements, wherein the input measurements comprise one or more measured properties of the fluid filled rocks and the output measurements comprise effective permeabilities of the fluid filled rocks;
constructing a mapping function using the input measurements and the output measurements;
receiving one or more input measurements made on one or more rocks that are not part of the collection of fluid filled rocks; and
predicting effective permeabilities of the rocks using the mapping function and the input measurements made on the rocks.

2. The method of claim 1, wherein the measurements are obtained from one or more laboratory or well logging measurements.

3. The method of claim 1, wherein the collection of fluid filled rocks comprises sandstones or carbonates.

4. The method of claim 1, wherein the rocks that are not part of the collection of fluid filled rocks comprise sandstones or carbonates.

5. The method of claim 1, wherein the input measurements comprise fluid saturations, porosity, Nuclear Magnetic Resonance (NMR) T2 response, NMR T1 response or combinations thereof.

6. The method of claim 1, wherein the mapping function is constructed using a linear combination of one or more non-linear functions.

7. The method of claim 6, wherein the non-linear functions are radial basis functions.

8. The method of claim 1, wherein the mapping function is constructed using a weighted sum of one or more non-linear functions.

9. The method of claim 1, wherein the mapping function is a multivariate interpolation function that interpolates the input measurements to the output measurements.

10. The method of claim 9, further comprising calibrating one or more coefficients of the multivariate interpolation function such that the interpolation of the input measurements to the output measurements is exact.

11. The method of claim 10, wherein predicting the effective permeability properties of the rocks comprises using the multivariate interpolation function with the coefficients to derive one or more depth logs of the effective permeability of the rocks.

12. The method of claim 1, further comprising predicting one or more flow rates of one or more fluids in the rocks using the predicted effective permeabilities of the rocks.

13. The method of claim 1, further comprising predicting mobilities of fluids in the rocks using the predicted effective permeabilities of the rocks.

14. The method of claim 13, wherein the mobilities are predicted by dividing the predicted effective permeabilities of the rocks by viscosities of the fluids in the rocks.

15. The method of claim 13, further comprising constructing a producibility index of the earth formations surrounding a well using the predicted mobilities.

16. The method of claim 13, further comprising predicting the flow rates of the fluids in the rocks using the predicted mobilities.

17. The method of claim 13, further comprising selecting casing perforation depths in a borehole penetrating the earth formations using the predicted mobilities, thereby optimizing production rates.

18. The method of claim 13, further comprising predicting a portion of a total flow from the earth formations penetrated by a borehole that will be water using the predicted mobilities.

19. The method of claim 1, wherein the predicted effective permeabilities of the rocks are related to hydrocarbons.

20. The method of claim 1, further comprising predicting continuous depth logs of the earth formations penetrated by a borehole based on the predicted effective permeabilities, the flow rates, the predicted mobilities, fractional water flow of the rocks, or combinations thereof.

21. The method of claim 1, further comprising creating one or more reservoir simulation models based on the predicted effective permeabilities or predicted mobilities of the rocks.

22. The method of claim 1, further comprising predicting relative permeabilities of the rocks by determining a ratio between the predicted effective permeabilities and absolute permeabilities.
